(19) United States
(12) Patent Application Publication
(10) Pub. No.: US 2007/0051400 A1
(43) Pub. Date: Mar. 8, 2007

(54) Thermoelectric converter

(75) Inventors: Shinji Aoki, Chiryu-city (JP); Yuji Ito, Okazaki-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/507,823

(22) Filed: Aug. 22, 2006

(30) Foreign Application Priority Data
Sep. 7, 2005 (JP) 2005-259701
May 11, 2006 (JP) 2006-133073

(51) Int. Cl. H01L 35/28

(52) U.S. Cl. 136/203

(57) ABSTRACT

In a thermoelectric converter, a division case (28, 29) is divided into first and second case portions (28, 29) to form air paths leading to a plurality of heat exchange members (25) defined into the heat absorption side and the heat radiation side. A waterproof film member (14) forming a waterproof film to prevent wetting of thermoelectric elements (12, 13) is formed on each surface of a first holding plate (11). The division case (28, 29) is so configured that the outer peripheral edge of the first holding plate (11) is held in the coupling surfaces of the first and second case portions (28, 29). At the same time, the first and second case portions (28, 29) are combined and held in such a manner as to press a pair of elastic members (30) against the outer peripheral edge of the first holding plate (11). As a result, wetting of the thermoelectric elements is suppressed and the durability, in terms of vibration resistance of the joints, is improved.

### BACKGROUND OF THE INVENTION

1. Field of the Invention

This invention relates to a thermoelectric converter for absorbing and radiating heat by supplying a DC current to a series circuit including N-type thermoelectric elements and P-type thermoelectric elements or, in particular, to a thermoelectric transducer suitably applicable to a cooling device or a heating device mounted on an automotive vehicle.

2. Description of the Related Art

A conventional thermoelectric converter of this type is known and is used in the cooling unit or the heating unit mounted on a vehicle. Specifically, a temperature control unit, having a thermoelectric converter constituted of a Peltier element and a blower, is accommodated in a vehicle seat and temperature-controlled air from the temperature control unit is blown out of the seat surface (Japanese Unexamined Patent Publication No. 2003-252036 (Patent Document 1)).

In a thermoelectric converter of this type, though not described in detail in Patent Document 1, but as disclosed in Japanese Unexamined Patent Publication No. 5-175556, a plurality of thermoelectric elements including N-type thermoelectric elements and P-type thermoelectric elements are arranged on a flat surface. A heat-absorbing heat exchange element is arranged on one surface of each thermoelectric element, while a heat-radiating heat exchange element is arranged on the other surface of each thermoelectric element. Adjacent thermoelectric elements are electrically connected in series by the electrodes thereof. In other words, a plurality of heat exchange elements are bonded to a plurality of thermoelectric elements by a bonding material such as solder.

Although Patent Document 1 fails to describe the structure for mounting the thermoelectric converter having a plurality of joints on the temperature control unit, in-vehicle applications generally require that a mounting structure having a plurality of joints is capable of with standing vehicle vibration.

These joints, if constantly exposed to vehicle vibration with frequent repetition of temperature cycles, pose the problem of a deteriorated durability in terms of a reduced vibration resistance.

Also, in the thermoelectric converter of this type, a plurality of thermoelectric elements are defined on a heat absorption side and on a heat radiation side and are connected to the joints of the thermoelectric elements. The dew generated on the heat absorption side may leak into the thermoelectric elements via through holes in a partitioning plate. In the case where an occupant spills water or the joints of the thermoelectric elements are otherwise wetted, migration may develop in the joints.

### SUMMARY OF THE INVENTION

Accordingly, it is an object of this invention to provide a thermoelectric converter which can prevent the wetting of the thermoelectric elements while, at the same time, improving the durability, in terms of vibration resistance, of the joints.

In order to achieve this object, according to one aspect of the invention, there is provided a thermoelectric converter comprising a thermoelectric element assembly (10) including a plurality of P-type thermoelectric elements (12), a plurality of N-type thermoelectric elements (13) and a first holding plate (11) for holding the plurality of the thermoelectric elements (12, 13) arranged thereon in predetermined pattern, a plurality of electrode elements (16) for electrically series-connecting each pair of thermoelectric elements (12, 13) adjacent to the thermoelectric element assembly (10), and a plurality of heat exchange elements (25) corresponding to the plurality of the electrode elements (16), respectively, wherein each pair of the thermoelectric elements (12, 13) and the corresponding electrode element (16) are directly connected to each other so that the plurality of the heat exchange elements (25) are defined into a heat absorption side and a heat radiation side, wherein a division case (28, 29) is adapted to be divided into first and second case portions (28, 29) to form air paths leading to the plurality of the heat exchange elements (25) defined into the heat absorption side and the heat radiation side, and wherein the outer peripheral edge of the first holding plate (11) is held in the joint surface of the first and second case portions (28, 29) of the division case (28, 29), and the first and second case portions (28, 29) are combined and held with a pair of elastic members (30) pressed against the outer peripheral edge of the first holding plate (11).

In this invention, the first holding plate (11) having a plurality of joints is held through the elastic members (30) which alleviate the vehicle vibrations generated on the division case (28, 29) and, therefore, the durability in terms of the vibration resistance of the plurality of the joints, including those of the thermoelectric elements (12, 13), is improved.

In this invention, the joint surface of the first and second case portions (28, 29) is formed with the holding surfaces (28a, 29a) in opposed relation to each other to press the outer peripheral edge of the first holding plate (11) through the elastic members (30).

In this invention, specifically, the holding surfaces (28a, 29a) are formed on the first and second case portions (28, 29) and, therefore, the vehicle vibration is absorbed by the holding surfaces (28a, 29a) and the surfaces of the elastic members (30). Thus, the vibration transmission to the first holding plate (11) is alleviated. As a result, the rigidity of the joints of the thermoelectric elements (12, 13) is secured.

In this invention, the holding surfaces (28a, 29a) are annular. In this invention, the hermeticity of the first and second case portions (28, 29) can be maintained both internally and externally while, at the same time, easily absorbing vibration in any direction.

In this invention, the elastic members (30) are each formed as an annular part of an elastic packing material low in impact resilience. In this invention, the vibrations can be alleviated satisfactorily, and the heat insulation of the outer peripheral edge of the first holding plate (11) is improved, thereby preventing the heat loss from this particular portion.

According to another aspect of the invention, there is provided a thermoelectric converter comprising a thermoelectric element assembly (10) including a plurality of P-type thermoelectric elements (12), a plurality of N-type thermoelectric elements (13), a first holding plate (11) for holding the plurality of the thermoelectric elements (12, 13) and a plurality of the thermoelectric elements (12, 13) arranged in predetermined pattern on the first holding plate (11), a plurality of electrode elements (16) for electrically series-connecting each pair of the thermoelectric elements (12, 13) adjacent to the thermoelectric element assembly (10) and a plurality of heat exchange elements (25) corresponding to the plurality of the electrode elements (16), respectively, wherein each pair of the thermoelectric elements (12, 13) and a corresponding electrode element (16) are connected in series to each other so that the plurality of the heat exchange elements (25) are defined into the heat absorption side and the heat radiation side, wherein a division case (28, 29) is adapted to be divided into first and second case portions (28, 29) thereby to form air paths leading to the plurality of the heat exchange elements (25) defined into the heat absorption side and the heat radiation side, and wherein the outer peripheral edge of the first holding plate (11) is held in the joint surface of the first and second case portions (28, 29) of the division case (28, 29), and the first and second cases (28, 29) are combined and held with the elastic members (30) pressed against the outside of the plurality of the heat exchange elements (25).

In this invention, the outside of the plurality of the heat exchange elements (25) and the first and second case portions (28, 29) are held through the elastic members (30), and therefore the vehicle vibrations generated on the division cases (28, 29) are alleviated by the elastic members (30). Thus, the durability in terms of the vibration resistance of the plurality of the joints including the joints of the thermoelectric elements (12, 13) is improved.

In this invention, each elastic member (30) is a tabular packing of an elastic material low in impact resilience. In this invention, the vibrations can be alleviated satisfactorily, while improving the hermeticity of the air paths to provide an improved heat exchange efficiency of the heat exchange elements (25).

In this invention, the first holding plate (11) has waterproof film members (14) formed on the surface thereof to prevent the wetting of the thermoelectric elements (12, 13). In the conventional thermoelectric converter of this type, dew may be formed on the heat absorption side and the first holding plate (11) may be wetted. According to this invention, however, the provision of the waterproof film members (14) suppresses the wetting of the joints between the electrode elements (16) and the thermoelectric elements (12, 13).

In this invention, the waterproof film members (14) are arranged by bonding on the outer peripheral edge of at least the first holding plate (11). In this invention, the waterproof film members (14) are held on the first and second case portions (28, 29) in such a manner as to contact the elastic members (30), and therefore no damage such as a cracking develops in the waterproof film members (14).

In this invention, a dehumidifying/insulating layer (17) for dehumidification and insulation is formed on the outer surface of the plurality of the heat exchange elements (25). In this invention, the plurality of the heat exchange elements (25) are each electrically insulated and therefore a shorting is prevented between adjacent heat exchange elements (25). Also, the migration which otherwise might be caused by the dew attached to the joints between the plurality of the heat exchange elements (25) and the electrode elements (16) is suppressed by the dehumidifying/insulating layer (17).

The present invention may be more fully understood from the description of preferred embodiments of the invention, as set forth below, together with the accompanying drawings.

### BRIEF DESCRIPTION OF THE DRAWINGS

FIG. 1 is a schematic diagram showing a general configuration of a thermoelectric converter according to a first embodiment of the invention.

FIG. 2 is an exploded view showing a general configuration of a thermoelectric converter according to the first embodiment of the invention.

FIG. 3 is a plan view showing the arrangement of a heat exchange members 25 on the heat absorbing side according to the first embodiment of the invention.

FIG. 4 is a bottom view showing the arrangement of the heat exchange members 25 on the heat radiation side according to the first embodiment of the invention.

FIG. 5 is a sectional view taken in line V-V in FIG. 3.

FIG. 6 is a sectional view taken in line VI-VI in FIG. 5.

FIG. 7 is a sectional view taken in line VII-VII in FIG. 5.

FIG. 8 is a sectional view taken in line VIII-VIII in FIG. 3.

FIG. 9 is a schematic diagram showing a general configuration of a thermoelectric converter according to a second embodiment of the invention.

FIG. 10 is a diagram for explaining the portion formed with the dehumidifying/insulating layer 17 according to another embodiment.

### DESCRIPTION OF THE PREFERRED EMBODIMENTS

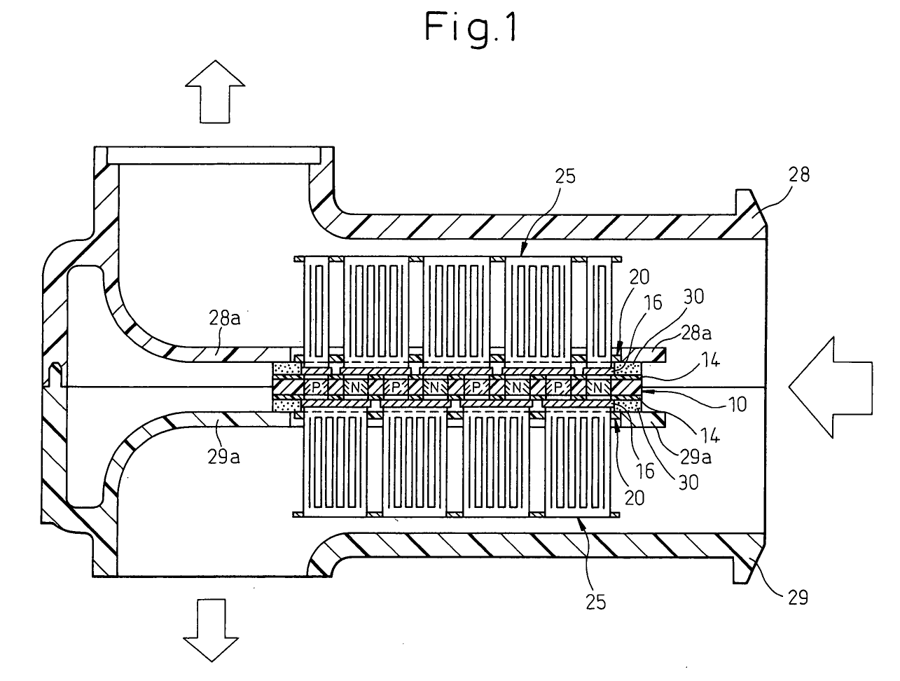

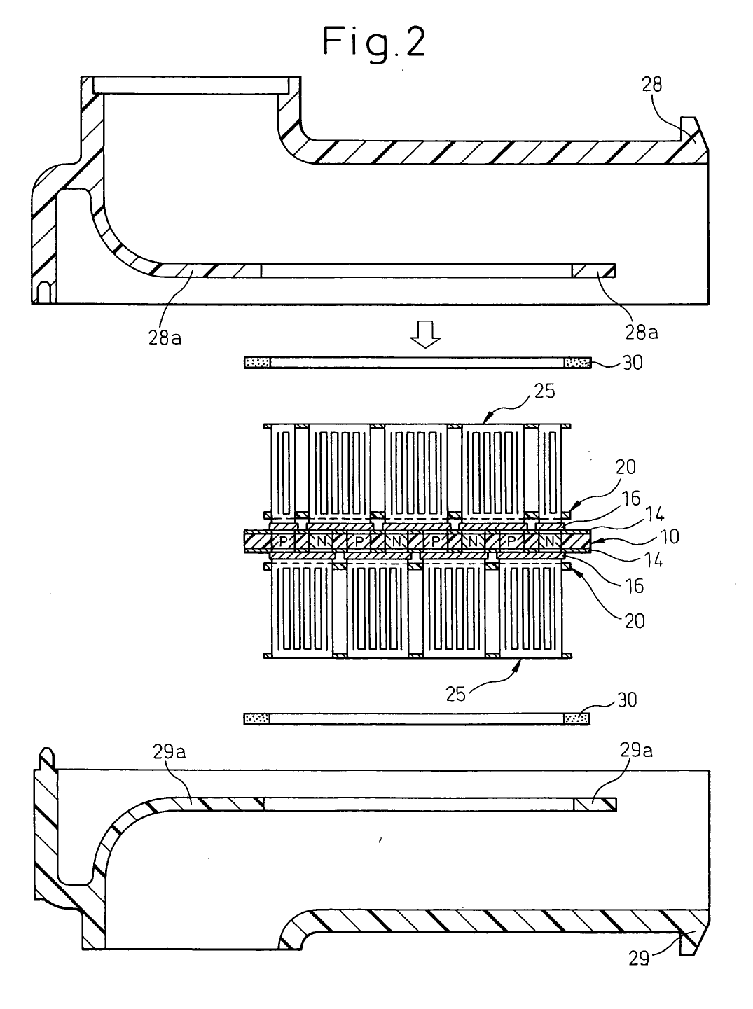

A thermoelectric converter according to a first embodiment of the invention is explained below with reference to FIGS. 1 to 9. FIG. 1 is a schematic diagram showing a general configuration of a thermoelectric converter according to the first embodiment of the invention. FIG. 2 is an exploded view showing a general configuration of the thermoelectric converter.

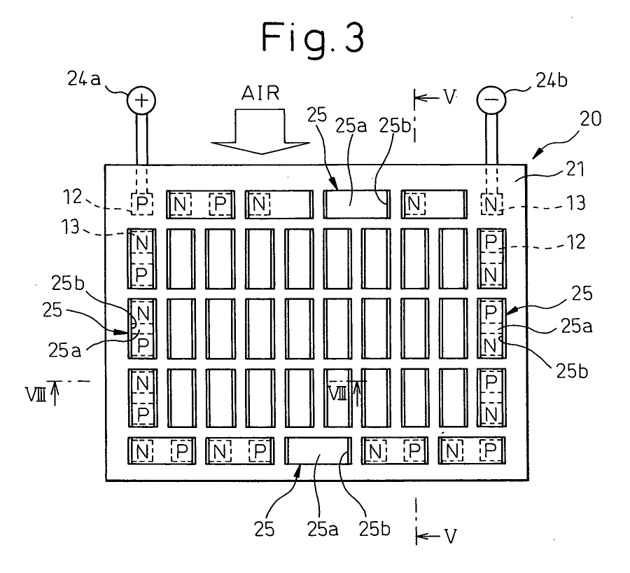

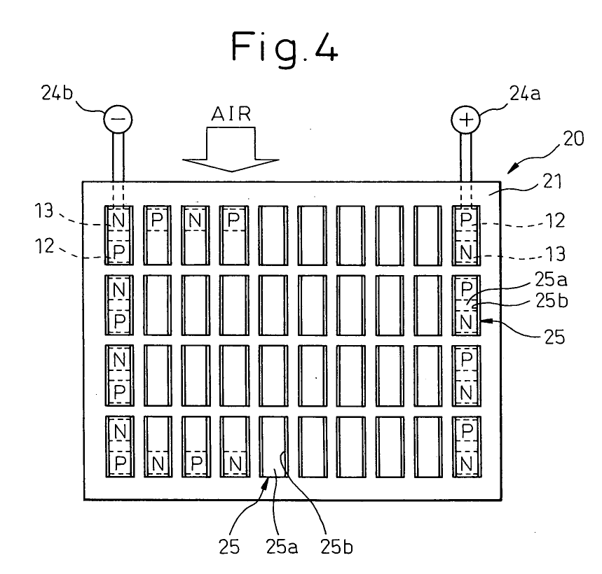

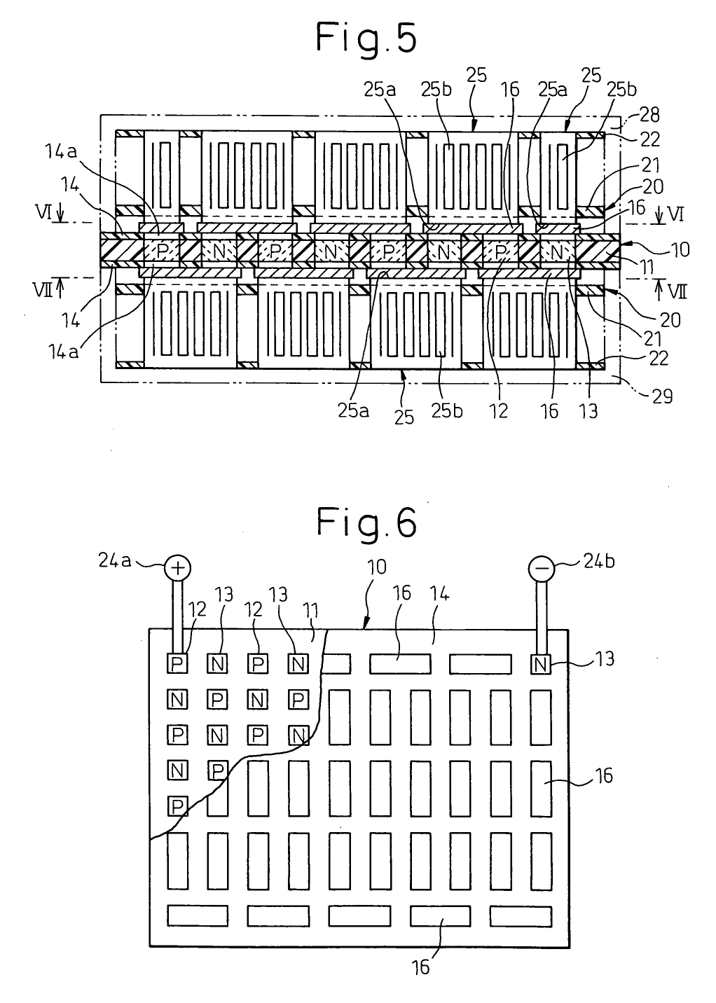

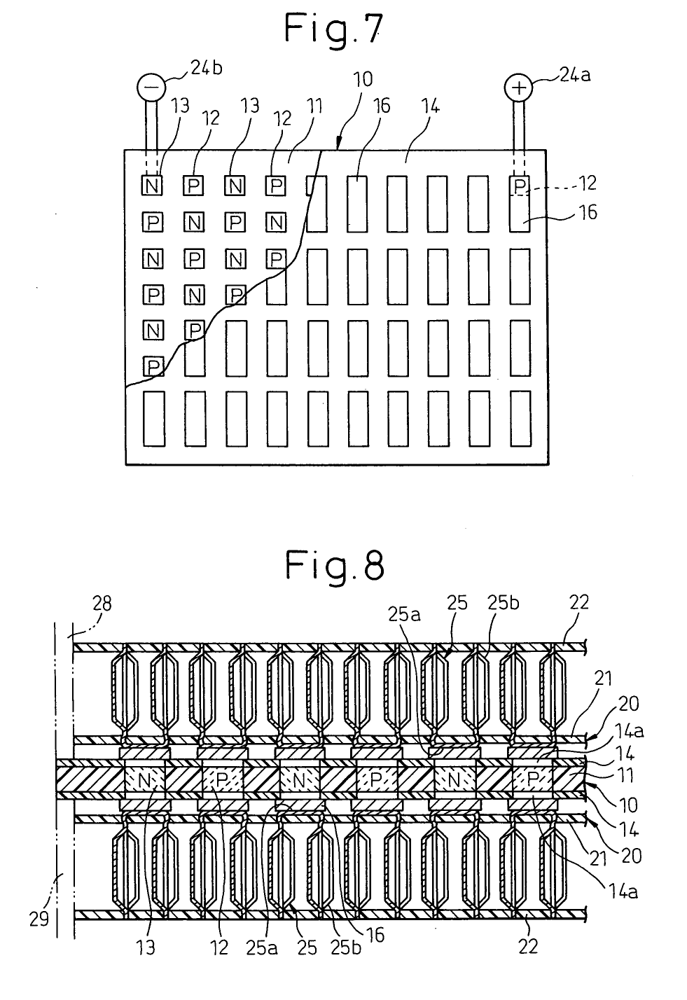

Also, FIG. 3 is a plan view showing the manner in which heat exchange members 25 are arranged on the heat absorption side. FIG. 4 is a bottom view showing the manner in which the heat exchange members 25 are arranged on the heat radiation side. FIG. 5 is a sectional view taken in line V-V in FIG. 3. FIG. 6 is a sectional view taken in line VI-VI in FIG. 5. FIG. 7 is a sectional view taken in line VII-VII in FIG. 5. FIG. 8 is a sectional view taken in line VIII-VIII in FIG. 3.

The thermoelectric converter according to this embodiment is used with a cooling unit or a heating unit mounted on an automotive vehicle. The thermoelectric transducer used for a seat air-conditioning system, for example, is arranged in each of the seat bottom and the backrest of the vehicle seat, and the cool air cooled by the thermoelectric converters is blown out from the seat surfaces.

The thermoelectric converter according to this embodiment, therefore, has a mounting structure adapted for a compact thermoelectric converter mountable in a limited installation space of the vehicle seat and is capable of absorbing vehicle vibrations.

First, the thermoelectric converter according to this embodiment, as shown in FIGS. 1, 2, 5, includes a thermoelectric element substrate 10 constituting a thermoelectric element assembly with an arrangement of a plurality of P-type and N-type thermoelectric elements 12. 13, electrode members 16 constituting electrode elements for electrically connecting adjacent thermoelectric elements 12, 13 in series to each other, heat-absorbing/radiating substrates 20 and division cases 28, 29 making up a pair of heat exchange element assemblies with a plurality of heat exchange members 25 constituting the heat exchange elements coupled to he electrode members 16 in a manner capable of heat transmission.

The thermoelectric element substrate 10 constituting the thermoelectric element assembly, as shown in FIGS. 6, 7, is configured of an integrated structure including a first holding plate 11 for holding thermoelectric elements having P-type and N-type thermoelectric elements 12, 13, a waterproof film member 14 and the electrode members 16.

Specifically, a plurality of pairs of a P-type thermoelectric element 12 and a N-type thermoelectric element 13 are arranged alternately in a substantially checkered form on the first holding plate 11 of a flat insulating material (such as glass epoxy, PPS resin, LCP resin or PET resin) thereby to constitute a group of thermoelectric elements, and each electrode member 16 is integrally coupled to the two end surfaces of the corresponding pair of adjacent thermoelectric elements 12, 13.

The P-type thermoelectric element 12 is configured of a P-type semiconductor of Bi—Te compound, and the N-type thermoelectric element 12 is a micro part configured of a N-type semiconductor of Bi—Te compound. Specifically, as shown in FIGS. 4, 5, the P-type thermoelectric elements 12 and the N-type thermoelectric elements 13 are formed in a substantially checkered arrangement in a predetermined way on the first holding plate 11.

The first holding plate 11 is formed with the outer peripheral edge thereof having at least substantially the same thickness as the height of the thermoelectric elements 12, 13. The thermoelectric elements 12, 13 arranged at the upper left and right corners in FIG. 6 have terminals 24a, 24b, respectively, which are connected to the positive and negative terminals, respectively, of a DC power supply not shown.

Each electrode member 16 constituting an electrode element is formed of a conductive metal such as a flat copper material and electrically connects a pair of adjacent P-type and the N-type thermoelectric elements 12, 13 of all the thermoelectric elements arranged on the thermoelectric element substrate 10.

Specifically, as shown in FIG. 5, each electrode member 16 arranged at an upper position supplies current from an adjacent N-type thermoelectric element 13 toward a P-type thermoelectric element 12. Each electrode member 16 arranged at a lower position, on the other hand, supplies current from an adjacent P-type thermoelectric element 12 to a N-type thermoelectric element 13.

All the electrode members 16 have a unified shape in plan view, i.e. are formed in a rectangle in such a size as to cover the end surfaces of the adjacent pair of the thermoelectric elements 12, 13. The electrode members 16 are thus arranged at predetermined positions and coupled to corresponding thermoelectric elements 12, 13, respectively, on the thermoelectric element substrate 10. The electrode members 16 are coupled by paste solder or the like, coated in a thin layer uniformly by screen printing, on the end surfaces of the thermoelectric elements 12, 13, respectively.

The electrode members 16 according to this embodiment, as shown in FIG. 5, are formed integrally with the waterproof film member 14, which is arranged on each surface of the first holding plate 11. In this way, each electrode member 16 is arranged at the end surfaces of the adjacent pair of the thermoelectric elements 12, 13.

The waterproof film member 14 is a sheet formed of, for example, a stack of thin films of thermoplastic polyimide or thermosetting polyimide. An electrode layer of copper foil is formed integrally on one surface of the sheet.

The electrode members 16 are formed on one surface of the waterproof film member 14 by etching, and a plurality of apertures 14a are formed at positions corresponding to the end surfaces of the plurality of the thermoelectric elements 12, 13, respectively. A waterproof film is formed by arranging this sheet over the whole of both surfaces of the first holding plate 11.

In this way, water is prevented from intruding into the joints for coupling the end surfaces of the thermoelectric elements 12, 13 and the electrode members 16. Each aperture 14a is substantially the same in size as the end surface of the thermoelectric elements 12, 13, and each electrode member 16 and the end surface of the corresponding thermoelectric elements 12, 13 are connected to each other through the aperture 14a.

The heat-absorbing/radiating substrates 20 constituting a heat exchange element assembly, as shown in FIGS. 3, 4, is configured of the heat exchanger members 25 constituting a plurality of heat exchange elements and the flat second holding plate 21 of an insulating material (glass epoxy, PPS resin, LCP resin or PET resin) integrated with each other.

Each heat exchange member 25 having a substantially U-shaped cross section, as shown in FIG. 8, is formed of a thin conductive metal plate of copper or the like, and has a flat electrode unit 25a on the bottom thereof and a louver-like heat exchange unit 25b on the flat surface extended outward of the electrode unit 25a.

The heat exchange unit 25b is a fin for absorbing/radiating the heat transmitted from the electrode unit 25a and is formed, integrally with the electrode unit 25a, by a cutup or the like forming process. The tabular electrode units 25a are formed integrally with the second holding plate 21 at predetermined positions corresponding to the arrangement of the electrode members 16.

The heat exchange members 25 are formed integrally on one surface of the second holding plate 21 in such a manner that one end surface of each electrode unit 25a is slightly projected. Specifically, the electrode unit 25a is not displaced toward the electrode member 16 when an end surface of the electrode unit 25a is coupled to the electrode member 16 arranged on the thermoelectric element substrate 10.

The plurality of the heat exchange members 25 are arranged on the second holding plate 21 with the electrode units 25a and the heat exchange unit 25b set in the same direction of air flow. More specifically, the heat exchange members 25 on one side of the thermoelectric element substrate 10 (FIG. 3) are arranged at predetermined positions in different patterns along the outer end, and inside the outer end, of the thermoelectric element group.

The heat exchange members 25 on the other side of the thermoelectric element substrate 10 (FIG. 4), in contrast, are arranged in four rows in the same manner as inside the outer end of the aforementioned thermoelectric element group. Further, a plurality of the heat exchange members 25 are arranged on the second holding plate 21 substantially in a checkered pattern with adjacent ones of the heat exchange members 25 electrically insulated from each other.

Reference numeral 22 designates a fixing plate constituting a holding member for holding the other end of each electrode unit 25a. This makes it possible to arrange adjacent heat exchange members 25 in a predetermined spaced relation with each other.

The fixing plate 22, like the second holding plate 21, is formed of a flat insulating material (such as glass epoxy, PPS resin, LCP resin or PET resin), and has a plurality of fixing holes, not shown, through which the other ends of the respective electrode units 25a are inserted.

The thermoelectric element substrate 10 is held between the pair of the absorbing/radiating substrates 20 including the heat absorption-side heat absorbing/radiating substrate 20 and the heat radiation-side heat absorbing/radiating substrate 20. These substrates are stacked and integrated by coupling the electrode members 16 and the electrode units 25a collectively by soldering.

The DC power input from the terminal 24a, as shown in FIG. 5, is supplied from the electrode member 16 above the P-type thermoelectric element 12 at the upper left corner to the particular P-type thermoelectric element 12 in FIG. 5, supplied as a series current to the right adjacent N-type thermoelectric element 13 through the underlying electrode member 16, and then from this N-type thermoelectric element 13, supplied as a series current to the right adjacent P-type thermoelectric element 12 through the upper electrode member 16.

In the process, the upper electrode member 16 making up the NP junction is reduced in temperature by the Peltier effect, while the lower electrode member 16 making up the PN junction increases in temperature. Specifically, the heat of low temperature is transmitted to, and contacts to a cooling fluid, the upper heat exchange unit 25b constituting a heat absorption-side heat exchange unit, while the heat of high temperature is transmitted to, and contacts to a fluid to be cooled, the lower heat exchange unit 25b constituting a heat radiation-side heat exchanger unit.

In other words, as shown in FIGS. 1, 5, air paths are formed, by the division cases 28, 29, on both sides of the thermoelectric element substrate 10 with the thermoelectric element substrate 10 as a partitioning wall, and by blowing air into the air paths, heat is exchanged between the heat exchange units 25b and the air. With the thermoelectric element substrate 10 as a partitioning wall, therefore, the air can be cooled by the upper heat exchange units 25b and heated by the lower heat exchange units 25b.

The division cases 28, 29 are formed by combining two division cases including a first case portion 28 and a second case portion 29 as shown in FIGS. 1, 2. The division cases 28, 29 are formed integrally by an appropriate resin such as polypropylene (PBT-M20GF20) containing a reinforcing agent.

Holding surfaces 28a, 29b are formed on the portions of the division cases 28, 29, respectively, in opposed relation to the outer peripheral edge of the first holding plate 11. The holding surfaces 28a, 29b are wider than the other surface combinations of the first and second cases 28, 29.

An elastic member 30 is held between each of the wide holding surfaces 28a, 29a and the outer peripheral edge of the first holding plate 11. Specifically, the first and second cases 28, 29 are combined in such a manner as to press the elastic members 30 against the outer peripheral edge of the first holding plate 11.

The holding surfaces 28a, 29a are annular and are formed in opposed relation to the outer peripheral edge of the first holding plate 11. The elastic members 30 are also annular and formed of an elastic packing material low in impact resilience such as PE-lite. Foamed urethane of an ether group is another candidate.

As a result, the elastic members 30 are held between the holding surfaces 28a, 29a and the outer peripheral edge of the first holding plate 11 under equal compressive forces. Any vehicle vibration shocks which may be exerted on the division cases 28, 29, therefore, can be absorbed and alleviated by the elastic members 30. In this way, only vehicle vibration alleviated by the elastic members 30 is propagated.

The division cases 28, 29 are integrally coupled to each other by fastening means such as metal spring clips or screws. The arrows in FIG. 1 indicate the directions of air flow. The air flow from a blower, not shown, forms separate air paths on the heat absorption side and the heat radiation side.

According to this embodiment, the positive terminal of the DC power supply is connected to the terminal 24a and the negative terminal to the terminal 24b so that DC power is input to the terminal 24a. Alternatively, however, the positive terminal of the DC power supply may be connected to the terminal 24b, and the negative terminal to the terminal 24a so that the DC power is input to the terminal 24b to reverse the direction of current. In such a case, however, the upper heat exchange units 25b form a heat-radiating heat exchange unit and the lower heat exchange units 25b a heat-absorbing heat exchange unit.

Next, a method of assembling the thermoelectric transducer having the aforementioned configuration is explained. First, the first holding plate 11 is formed to the thickness substantially equal to the height (about 0.95 mm to 1.0 mm, for example) of the thermoelectric elements 12, 13. As shown in FIGS. 6, 7, the thermoelectric elements 12, 13 of P and N types are arranged alternately in the substrate holes formed in the first holding plate 11 in a predetermined substantially checkered arrangement.

As a result, the end surfaces of the plurality of the thermoelectric elements 12, 13 are arranged in the same plane on one end surface and the other end surface of the first holding plate 11. In this way, the plurality of the thermoelectric elements 12, 13 are formed integrally on the first holding plate 11. For the purpose of arranging the plurality of the thermoelectric elements 12, 13 on the first holding plate 11, a mounter may be used, as fabrication equipment, to assemble the semiconductors and the electronic parts on the control board.

Next, the electrode members 16 and the waterproof film members 14 are formed integrally with each other. More specifically, a copper foil layer (about 300 μm, for example) is integrally formed on one surface of the waterproof film member 14 formed as a stack of a thermosetting polyimide layer (5 μm, for example), a thermoplastic polyimide layer (25 μm, for example) and a thermoplastic polyimide layer (5 μm, for example).

Then, the electrode members 16 of a predetermined shape are formed by etching while, at the same time, forming apertures 14a at the portions of the waterproof film member 14 corresponding to the end surfaces of the plurality of the thermoelectric elements 12, 13, respectively. Each waterproof film member 14 is formed to cover the whole surface of the first holding plate 11.

As a result, the electrode members 16 are formed to cover the apertures 14a, and the outer edge of each electrode member 16 is coupled to the thermoplastic layer (5 μm, for example) of the corresponding waterproof film member 14. Thus, the plurality of the electrode members 16 can be collectively formed, while at the same time covering the apertures 14a with the outer edges of the electrode members 16.

Then, the end surfaces of the thermoelectric elements 12, 13 arranged on the first holding plate 11 are coated with a thin uniform film of solder paste or the like by screen printing, after which the waterproof film members 14 having the electrode members 16 are arranged on the surface of the first holding plate 11.

The outer edges of at least the apertures 14a formed outside are coupled by welding to the outer peripheral edge of the first holding plate 11. As a result, the upper electrode members 16 each form a NP junction, while the lower electrode members 16 each form a PN junction thereby to connect the thermoelectric elements 12, 13 in series to each other. In this way, a waterproof film is formed on each of the two surfaces of the first holding plate 11.

The thermoelectric element substrate 10 in this state is loaded into a high-temperature furnace, and the electrode members 16 and the end surfaces of the thermoelectric elements 12. 13 are collectively coupled to each other. As a result, the plurality of the electrode members 16 are coupled to the end surfaces of the thermoelectric elements 12, 13 at the same time and in such a manner as to cover the apertures 14a.

The heat absorbing/radiating substrates 20, as shown in FIGS. 3, 4, are integrally formed on the second holding plates 21 in provisionally fixed state with the electrode unit 25a fitted into the substrate hole, not shown, formed in the second holding plate 21.

As shown in FIG. 5, while the thermoelectric element substrate 10 is held between the heat absorption-side heat absorbing/radiating substrate 20 and the heat radiation-side heat absorbing/radiating substrate 20, the electrode members 16 and the electrode units 25a are collectively coupled to each other by soldering. As a result, the thermoelectric element substrate 10 and the pair of the heat absorbing/radiating substrates 20 are integrally configured.

As shown in FIGS. 1 and 2, the elastic member 30 is arranged on the holding surface 29a of the second case portion 29 while, at the same time, arranging the outer peripheral edge of the first holding plate 11 on the upper surface of the elastic member 30. The other elastic member 30 is arranged on the outer peripheral edge of the first holding plate 11, and the holding surface 28a of the first case portion 28 is combined on the upper surface of the elastic member 30. In this way, the first case portion 28 and the second case portion 29 are coupled to each other by a fastening means not shown.

As a result, the thermoelectric element substrate 10 and the heat absorbing/radiating substrate 20 are accommodated in the division case portions 28, 29, and an air path on heat absorption side is formed in the upper part of the division case portions 28, 29, while the air path on the heat radiation side is formed in the lower part of the division case portions 28, 29. Specifically, the heat absorbing heat exchange unit is formed at an upper position, while a heat radiating heat exchange unit is formed at a lower position. By supplying the air through these air paths, cool or warm air can be obtained.

As the result of forming the heat absorbing heat exchange unit at an upper position, dew may be formed and the water leaking from the through hole of the second holding plate 21 may wet the first holding plate 11. In view of the fact that the waterproof film member 14 forms a waterproof film on the first holding plate 11 and the apertures 14a are covered by the electrode members 16, however, the joints are not wetted.

Also, the thermoelectric element substrate 10 having a plurality of the joints is held by the division cases 28, 29 through the elastic members 30 capable of absorbing the vehicle vibrations. As a result, the vibration of the first holding plate 11 is damped and the rigidity of the joints is maintained. Thus, the durability in terms of the vibration resistance of the joints is improved.

In the conventional thermoelectric transducer similar to the first embodiment described above, dew may develop on the heat absorption side and wet the first holding plate 11. According to this embodiment, however, the provision of the waterproof film member 14 can suppress the wetting of the joints of the electrode members 16 and the thermoelectric elements 12, 13.

Also, the outer peripheral edge of the first holding plate 11 is held in the joint surface of the first and second case portions 28, 29, and the first and second case portions 28, 29 are combined in such a manner as to press the elastic members 30 against the outer peripheral edge of the first holding plate 11.

As a result, the first holding plate 11 having a plurality of the joints is held through the elastic members 30 and, therefore, the vehicle vibration generated on the division cases 28, 29 is alleviated by the elastic members 30. Thus, the durability, in terms of the vibration resistance, of the plurality of the joints, including those of the thermoelectric elements 12, 13, can be improved.

Also, the holding surfaces 28a, 29a for pressing the outer peripheral edge of the first holding plate 11 are formed in opposed relation to each other through the elastic members 30 on the joint surfaces between the first and second case portions 28, 29.

By forming the holding surfaces 28a, 29a on the division cases 28, 29 in this way, vehicle vibration is absorbed into the holding surfaces 28a, 29a and the elastic members 30, thereby alleviating the vibration transmitted to the first holding plate 11. As a result, the rigidity of the joints of the thermoelectric elements 12, 13 can be secured.

Further, the holding surfaces 28a, 29a are formed in annular shape, and therefore both internal and external hermeticity of the first and second case portions 28, 29 can be maintained while, at the same time, making it possible to absorb vibration from any direction.

In view of the fact that the elastic members 30 are formed of an annular elastic packing material low in impact resilience, the vibrations are alleviated satisfactorily, on the one hand, while the improved heat insulation at the outer peripheral edge of the first holding plate 11 prevents the heat loss in these parts, on the other hand.

Furthermore, the waterproof film members 14 are arranged and coupled at least to the outer peripheral edge of the first holding plate 11 and, thus, are held by the first and second case portions 28, 29 in contact with the elastic members 30. Thus, damage such as cracking of the waterproof members 14 is avoided.

### Second Embodiment

In the first embodiment described above, the elastic members 30 are held on the holding surfaces 28a, 29a of the case portions 28, 29 in such a manner as to press the elastic members 30 against the outer peripheral edge of the first holding plate 11. The invention, however, is not limited to this configuration, and the elastic members 30 may be held on the inner peripheral surface of the case portions 28, 29 while being pressed against the outside of the plurality of the heat exchange members 25.

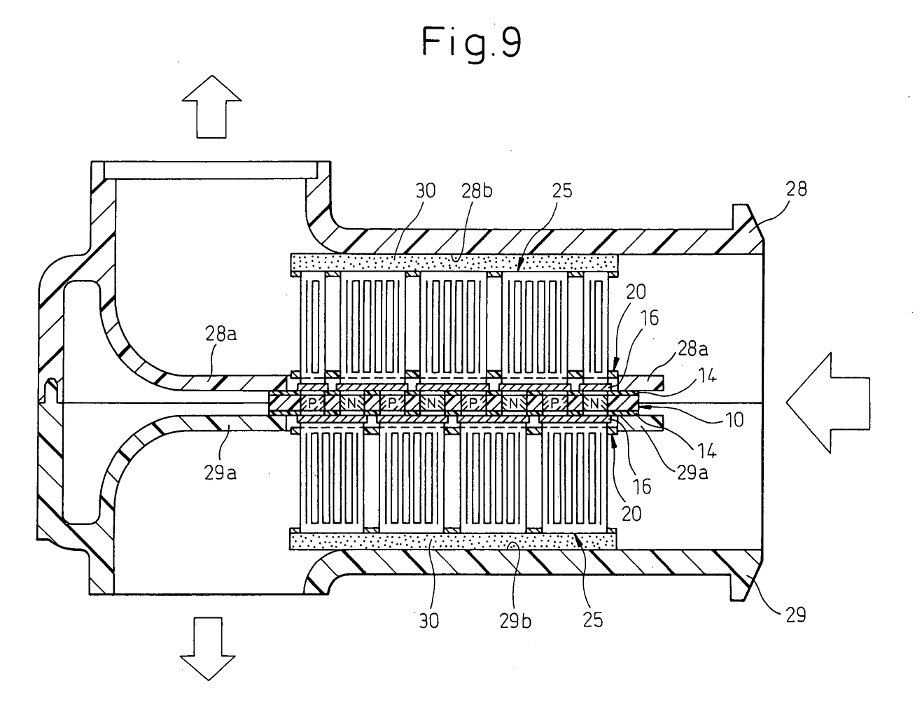

Specifically, as shown in FIG. 9, the elastic members 30 are arranged in the gaps between the outside of the plurality of the heat exchange members 25 and the inner peripheral surfaces 28b, 29b of the case portions 28, 29, and the first and second case portions 28, 29 are combined while pressing the elastic members 30 against the inner peripheral surfaces 28b, 29b.

The outer peripheral edge of the first holding plate 11 is held by the joint surfaces, i.e. the holding surfaces 28a, 29a of the first and second case portions 28, 29. As a result, the elastic members 30 are held with the compressive force exerted equally on each of the inner peripheral surfaces 28b, 29b and the outside of the plurality of the heat exchange members 25.

The vehicle vibrations which may be exerted on the division cases 28, 29, therefore, can be alleviated by being absorbed into the elastic members 30. In other words, the vibrations can be reduced satisfactorily while at the same time improving the hermeticity of the air paths for an improved heat exchange efficiency of the heat exchange members 25.

According to this embodiment, the elastic members 30 are arranged in the gaps between the outside of the plurality of the heat exchange members 25 and the inner peripheral surfaces 28b, 29b of the case portions 28, 29. This invention, however, is not limited to this configuration, and the elastic members 30 may alternatively be arranged only on the outer upper side or the outer lower side of the heat exchange members 25.

Also, the first and second case portions 28, 29 can be combined through a hermetic member, not shown, such as a packing material between the outer peripheral edge of the first holding plate 11 and the holding surfaces 28a, 29a. As a result, the heat insulation at the outer peripheral edge of the first holding plate 11 is improved and a heat loss from this particular part can be prevented.

### Other Embodiments

In the embodiments described above, the electrode members 16 are formed integrally with the waterproof film members 14 and are coupled to the end surfaces of the thermoelectric elements 12, 13. The invention, however, is not limited to this configuration, and the electrode members 16 may be flat in form and coupled to the end surfaces of the thermoelectric elements 12, 13.

Also, in the aforementioned embodiments, the waterproof films are formed by arranging the waterproof film members 14 of polyimide over the whole of one and the other surfaces of the first holding plate 11. As an alternative, however, the electrode members 16 in a flat form are coupled to the end surfaces of the thermoelectric elements 12, 13 to form the thermoelectric element substrate 10. Then, this thermoelectric element substrate 10 may be held between the heat absorption-side heat absorbing/radiating substrate 20 and the heat radiation-side heat absorbing/radiating substrate 20, and after the electrode members 16 and the electrode units 25a are coupled to each other, a waterproof insulating material of epoxy group may be coated on the outer surface of the thermoelectric element substrate 10 to thereby form a waterproof layer.

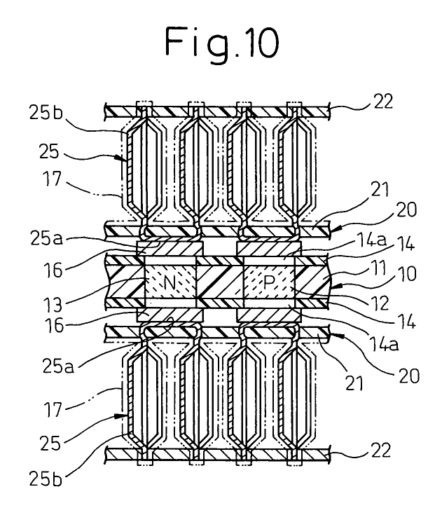

Further, as shown in FIG. 10, the dehumidifying/insulating layers 17 for dehumidification and insulation may be formed by electrodeposition coating using an epoxy resin material on the outer surface of the plurality of the heat exchange members 25. This electrodeposition coating is preferably carried out before coating the waterproof insulating material on the outer surface of the thermoelectric element substrate 10.

By so doing, the plurality of the heat exchange members 25 are electrically insulated from each other so that shorting is prevented between adjacent heat exchange members 25. Also, the migration which otherwise might be caused by the dew attached to the joints between the plurality of the heat exchange members 25 and the electrode members 16 can be suppressed by the dehumidifying/insulating layers 17.

Furthermore, instead of the configuration according to the aforementioned embodiments in which the whole outer peripheral edge of the first holding plate 11 is held by the division case portions 28, 29, a configuration may be employed in which the outer peripheral edge of the first holding plate 11 is partially held. As another alternative, only the left and right ends or the front and rear ends of the outer peripheral edge of the first holding plate 11 may be held.

What is more, the invention is not limited to the configuration in which the heat exchange units 25b of the heat exchange members 25 are formed into the shape of louver as in the above-mentioned embodiments. Instead, the heat exchange units 25b may be offset.

While the invention has been described by reference to specific embodiments chosen for purposes of illustration, it should be apparent that numerous modifications could be made thereto, by those skilled in the art, without departing from the basic concept and scope of the invention.

1. A thermoelectric converter comprising:
a thermoelectric element assembly including a plurality of P-type thermoelectric elements, a plurality of N-type thermoelectric elements and a tabular first holding plate for holding the plurality of the thermoelectric elements arranged thereon in a predetermined pattern;
a plurality of electrode elements each for electrically connecting a pair of thermoelectric elements adjacent to the thermoelectric element assembly; and
a plurality of heat exchange elements corresponding to the plurality of the electrode elements, respectively;
wherein each pair of the thermoelectric elements and the corresponding electrode elements are electrically connected directly to each other so that the plurality of the heat exchange elements are defined into the heat absorption side and the heat radiation side,
wherein a division case is divided into first and second case portions to form air paths leading to the plurality of the heat exchange elements defined into the heat absorption side and the heat radiation side,
wherein the outer peripheral edge of the first holding plate is held between the coupling surfaces of the first and second case portions of the division case, and
wherein the first and second case portions are combined and held in such a manner as to press a pair of elastic members against the outer peripheral edge of the first holding plate.

2. A thermoelectric converter according to claim 1,
wherein the coupling surface of the first and second case portions is formed with the holding surfaces in opposed relation to each other to press the outer peripheral edge of the first holding plate through the elastic members.

3. A thermoelectric converter according to claim 2,
wherein the holding surfaces are annular.

4. A thermoelectric converter according to claim 1,
wherein the elastic members are annular and formed of an elastic packing low in repulsiveness.

5. A thermoelectric converter according to claim 1,
wherein the first holding plate has a waterproof film member formed on the surface thereof to prevent wetting of the thermoelectric elements.

6. A thermoelectric converter according to claim 5,
wherein the waterproof film member is arranged by being coupled to at least the outer peripheral edge of the first holding plate.

7. A thermoelectric converter according to claim 1,
wherein the plurality of the heat exchange elements have the outer surface thereof formed with a dehumidifying/insulating layer for dehumidification and insulation.

8. A thermoelectric converter comprising:
a thermoelectric element assembly including a plurality of P-type thermoelectric elements, a plurality of N-type thermoelectric elements and a first tabular holding plate for holding the plurality of the thermoelectric elements, the plurality of the thermoelectric elements being arranged in a predetermined pattern on the first holding plate;
a plurality of electrode elements for electrically connecting each pair of the thermoelectric elements in series on the thermoelectric element assembly; and
a plurality of heat exchange elements corresponding to the plurality of the electrode elements, respectively;
wherein each pair of the thermoelectric elements and the corresponding electrode elements are electrically connected in series to each other so that the plurality of the heat exchange elements are defined into the heat absorption side and the heat radiation side,
wherein a division case is divided into first and second case portions to form air paths leading to the plurality of the heat exchange elements defined into the heat absorption side and the heat radiation side,
wherein the outer peripheral edge of the first holding plate is held on the coupling surface of the first and second case portions of the division case, and
wherein the first and second case portions are combined and held in such a manner as to press elastic members against the outside the plurality of the heat exchange elements.

9. A thermoelectric converter according to claim 8,
wherein each of the elastic members is a tabular packing member of an elastic material low in impact resilience.

10. A thermoelectric converter according to claim 8,
wherein a waterproof film member, constituting a waterproof film to prevent wetting of the thermoelectric elements, is formed on the surface of the first holding plate.

11. A thermoelectric converter according to claim 10,
wherein the waterproof member is arranged by being coupled to at least the outer peripheral edge of the first holding plate.

12. A thermoelectric converter according to claim 8,
wherein a dehumidifying/insulating layer for dehumidification and insulation is formed on the outer surface of the plurality of the heat exchange elements.
